(19) United States
(12) Patent Application Publication
(10) Pub. No.: US 2010/0147210 A1
(43) Pub. Date: Jun. 17, 2010

(54) HIGH PRESSURE APPARATUS AND METHOD FOR NITRIDE CRYSTAL GROWTH

(75) Inventor: MARK P. D'EVELYN, Goleta, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Soraa, Inc., Goleta, CA (US)

(21) Appl. No.: 12/334,418

(22) Filed: Dec. 12, 2008

(51) Int. Cl. C30B 19/08

(52) U.S. Cl. 117/81; 117/223

(57) ABSTRACT

An improved high pressure apparatus and related methods for processing supercritical fluids. In a specific embodiment, the present apparatus includes a capsule, a release sleeve, a heater, at least one ceramic segment or ring but can be multiple segments or rings, optionally, with one or more scribe marks and/or cracks present. In a specific embodiment, the apparatus optionally has a metal sleeve containing each ceramic ring. The apparatus also has a high-strength enclosure, end flanges with associated insulation, and a power control system. In a specific embodiment, the apparatus is capable of accessing pressures and temperatures of 0.2-2 GPa and 400-1200° C., respectively. Following a run, the release sleeve may be at least partially dissolved or etched to facilitate removal of the capsule from the apparatus.

### CROSS-REFERENCES TO RELATED APPLICATIONS

NOT APPLICABLE

### STATEMENT AS TO RIGHTS TO INVENTIONS MADE UNDER FEDERALLY SPONSORED RESEARCH OR DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

The present invention relates generally to techniques for processing materials in supercritical fluids. More specifically, embodiments of the invention include techniques for material processing in a capsule disposed within a high-pressure apparatus enclosure. Merely by way of example, the invention can be applied to growing crystals of GaN, AlN, InN, InGaN, AlGaN, and AlInGaN, and others for manufacture of bulk or patterned substrates. Such bulk or patterned substrates can be used for a variety of applications including optoelectronic devices, lasers, light emitting diodes, solar cells, photoelectrochemical water splitting and hydrogen generation, photodetectors, integrated circuits, and transistors, among other devices.

Supercritical fluids are used to process a wide variety of materials. A supercritical fluid is often defined as a substance beyond its critical point, i.e., critical temperature and critical pressure. A critical point represents the highest temperature and pressure at which the substance can exist as a vapor and liquid in equilibrium. In certain supercritical fluid applications, the materials being processed are placed inside a pressure vessel or other high pressure apparatus. In some cases it is desirable to first place the materials inside a container, liner, or capsule, which in turn is placed inside the high pressure apparatus. In operation, the high pressure apparatus provides structural support for the high pressures generated within the container or capsule holding the materials. The container, liner, or capsule provides a closed/sealed environment that is chemically inert and impermeable to solvents, solutes, and gases that may be involved in or generated by the process.

Scientists and engineers have been synthesizing crystalline materials using high pressure techniques. As an example, synthetic diamonds are often made using high pressure and temperature conditions. Synthetic diamonds are often used for industrial purposes but can also be grown large enough for jewelry and other applications. Scientists and engineers also use high pressure to synthesize complex materials such as zeolites, which can be used to filter toxins and the like. Moreover, geologists have also used high pressure techniques to simulate conditions and/or processes occurring deep within the earth's crust. High pressure techniques often rely upon supercritical fluids, herein referred to as SCFs.

Supercritical fluids provide an especially ideal environment for growth of high quality crystals in large volumes and low costs. In many cases, supercritical fluids possess the solvating capabilities of a liquid with the transport characteristics of a gas. Thus, on the one hand, supercritical fluids can dissolve significant quantities of a solute for recrystallization. On the other hand, the favorable transport characteristics include a high diffusion coefficient, so that solutes may be transported rapidly through the boundary layer between the bulk of the supercritical fluid and a growing crystal, and also a low viscosity, so that the boundary layer is very thin and small temperature gradients can cause facile self-convection and self-stirring of the reactor. This combination of characteristics enables, for example, the growth of hundreds or thousands of large α-quartz crystals in a single growth run in supercritical water.

Supercritical fluids also provide an attractive medium for synthesis of exotic materials, such as zeolites, for solvent extractions, as of caffeine from coffee, and for decomposition and/or dissolution of materials that are relatively inert under more typical conditions, such as biofuels and toxic waste materials.

In some applications, such as crystal growth, the pressure vessel or capsule also includes a baffle plate that separates the interior into different chambers, e.g., a top half and a bottom half. The baffle plate typically has a plurality of random or regularly spaced holes to enable fluid flow and heat and mass transfer between these different chambers, which hold the different materials being processed along with a supercritical fluid. For example, in typical crystal growth applications, one portion of the capsule contains seed crystals and the other half contains nutrient material. In addition to the materials being processed, the capsule contains a solid or liquid that forms the supercritical fluid at elevated temperatures and pressures and, typically, also a mineralizer to increase the solubility of the materials being processed in the supercritical fluid. In other applications, for example, synthesis of zeolites or of nano-particles or processing of ceramics, no baffle plate may be used for operation. In operation, the capsule is heated and pressurized toward or beyond the critical point, thereby causing the solid and/or liquid to transform into the supercritical fluid. In some applications the fluid may remain subcritical, that is, the pressure or temperature may be less than the critical point. However, in all cases of interest here, the fluid is superheated, that is, the temperature is higher than the boiling point of the fluid at atmospheric pressure. The term “supercritical” will be used throughout to mean “superheated”, regardless of whether the pressure and temperature are greater than the critical point, which may not be known for a particular fluid composition with dissolved solutes.

Although somewhat effective for conventional crystal growth, drawbacks exist with conventional processing vessels. As an example, processing capabilities for conventional steel hot-wall pressure vessels (e.g., autoclaves) are typically limited to a maximum temperature of about 400 Degrees Celsius and a maximum pressure of 0.2 GigaPascals (GPa). Fabrication of conventional pressure vessels from nickel-based superalloys allows for operation at a maximum temperature of about 550 degrees Celsius and a maximum pressure of about 0.5 GPa. Therefore, these conventional hot-wall pressure vessels are often inadequate for some processes, such as the growth of gallium nitride crystals in supercritical ammonia that often require pressures and temperatures that extend significantly above this range in order to achieve growth rates above about 2-4 microns per hour. In addition, nickel-based superalloys are very expensive and are difficult to machine, limiting the maximum practical size and greatly increasing the cost compared to traditional steel pressure vessels.

Attempts have been made to overcome the drawbacks of conventional pressure vessels. D'Evelyn et al., US patent application 2003/0140845A1, indicates a so-called zero-stroke high pressure apparatus adapted from the type of belt apparatus used for synthesis of diamond using high pressure and high temperature. Cemented tungsten carbide, however, is used as the die material, which is relatively expensive and is difficult to manufacture in large dimensions. In addition, the use of a hydraulic press to contain the apparatus increases the cost and further limits the maximum volume. Finally, the use of a pressure transmission medium into which the heater is inserted and which surrounds the capsule used to contain the supercritical fluid reduces the volume available within the hot zone for processing material and limits the heater to a single use.

D'Evelyn et al., US patent application 2006/0177362A1, indicates several types of apparatus with capability for pressures and temperatures well in excess of that of conventional autoclaves and with improved scalability relative to the zero-stroke press apparatus described above. A series of wedge-shaped radial ceramic segments are placed between a heater which surrounds a capsule and a high-strength enclosure, in order to reduce both the pressure and temperature to which the inner diameter of the high-strength enclosure is exposed compared to the corresponding values for the capsule. The capsule is indicated as being in direct contact with the heater, and the only means taught for removal of the capsule at the conclusion of a run is the use of a sleeve with a higher thermal expansion coefficient than the body of the capsule. However, if the sleeve deforms during the process and becomes affixed to the heater, removal of the capsule may be difficult. D'Evelyn et al., US patent application 2008/0083741A1, teaches sliding removal of the capsule, using a hydraulic piston to press the capsule out from the inside of the heater. However, such an operation may deform the capsule, possibly damaging crystals contained inside. These and other limitations of conventional apparatus may be described throughout the present specification.

From the above, it is seen that techniques for improving a high pressure apparatus for crystal growth is highly desirable.

### BRIEF SUMMARY OF THE INVENTION

According to the present invention, techniques related for processing materials in supercritical fluids are provided. More specifically, embodiments of the invention include techniques for material processing in a capsule disposed within a high-pressure apparatus/enclosure. Merely by way of example, the invention can be applied to growing crystals of GaN, AlN, InN, InGaN, AlGaN, and AlInGaN, and others for manufacture of bulk or patterned substrates. Such bulk or patterned substrates can be used for a variety of applications including optoelectronic devices, lasers, light emitting diodes, solar cells, photo electrochemical water splitting and hydrogen generation, photodetectors, integrated circuits, and transistors, and others.

In a specific embodiment, the present invention provides a high pressure apparatus and related methods for processing supercritical fluids. In a specific embodiment, the present apparatus includes a capsule, a heater, at least one ceramic ring but can be multiple rings, optionally, with one or more scribe marks and/or cracks present. In a specific embodiment, the apparatus optionally has a metal sleeve containing each ceramic ring. The apparatus also has a high-strength enclosure, end flanges with associated insulation, and a power control system. The apparatus is scalable up to very large volumes and is cost effective. In a specific embodiment, the apparatus is capable of accessing pressures and temperatures of 0.2-2 GPa and 400-1200° C., respectively. As used herein in a specific embodiment, the term “high-strength” generally means suitable mechanical and other features (e.g., tensile strength, Young's Modulus, yield strength, toughness, creep resistance, chemical resistance) that allow for use as a high pressure enclosure, such as a pressure vessel, which may be airtight, but may also not be air and/or gas tight). As an example, the term “high pressure” generally refers to above 0.1 GPa, 0.2 GPa, 0.5 GPa, and others, particularly in pressures suitable for growth of crystalline materials, including but not limited to GaN, AlN, InN, AlGaN, InGaN, AlInGaN, and other nitrides or oxides or metal or dielectric or semiconducting materials. In a specific embodiment, the high strength enclosure material is provided to form a high strength enclosure configured to withstand a load of greater than about 0.1 GPa (or 0.2 GPa or 0.5 GPa) for a predetermined time period at a temperature of about 200 Degrees Celsius or less. In a preferred embodiment, the apparatus has a release sleeve disposed between the cylindrical capsule region and the annular heating member. Preferably, the release sleeve is configured to be dissolved and/or etched under one or more process conditions without producing substantial dissolution and/or etching of the annular heating member. Of course, there can be other variations, modifications, and alternatives.

In an alternative specific embodiment, the present invention provides apparatus for high pressure crystal or material processing, e.g., GaN, AlN, InN, InGaN, AlGaN, and AlInGaN. In a specific embodiment, the apparatus has a cylindrical capsule region comprising a first region and a second region, and a length defined between the first region and the second region. The apparatus has an annular heating member overlying a release sleeve, which encloses (fully or partially) the length of the cylindrical capsule region. In a preferred embodiment, the release sleeve is configured to be dissolved and/or etched under one or more process conditions without producing substantial dissolution and/or etching of the annular heating member. The apparatus also has at least one annular metal or cermet member having a predetermined thickness disposed continuously around a perimeter of the annular heating member. In a preferred embodiment, the continuous annular member is made of a material having a compressive strength of about 0.5 GPa and greater and a thermal conductivity of about 100 watts per meter-Kelvin and less. The apparatus has a high strength enclosure material disposed overlying the annular metal or cermet member to form a high strength enclosure.

In a specific embodiment, the present invention provides a method of crystal growth. The method includes providing an apparatus for high pressure crystal or material processing. In a preferred embodiment, the apparatus is configured similar to those noted herein and outside the specification and more preferably includes an annular heating member overlying a release sleeve, which fully or partially encloses the length of the cylindrical capsule region. In a preferred embodiment, the release sleeve is configured to be dissolved and/or etched under one or more process conditions without producing substantial dissolution and/or etching of the annular heating member. The method includes providing a capsule containing a solvent. The method places the capsule within an interior region of the cylindrical capsule region and processes the capsule with thermal energy to cause an increase in temperature within the capsule to greater than 200 Degrees Celsius to cause the solvent to be superheated. After processing, the capsule is removed by dissolving and/or etching the release sleeve to free the capsule from an interior region of the apparatus without substantial deformation and/or damage of the annular heating member and/or capsule. Of course, there can be other variations, modifications, and alternatives.

Moreover, depending upon the embodiment, the present method can also include one of a plurality of optional steps. Optionally, the method includes forming a crystalline material from a process of the superheated solvent. Additionally, the method includes removing thermal energy from the capsule to cause a temperature of the capsule to change from a first temperature to a second temperature, which is lower than the first temperature. The method also includes removing a first flange and a second flange from the high pressure apparatus and moving a mechanical member, using a hydraulic drive force, from the first region of the cylindrical capsule region toward the second region to transfer the capsule out of the cylindrical capsule region. In a preferred embodiment, the present apparatus can be scaled up in size to a capsule volume of 0.3 liters, to about 300 liters and greater. Of course, there can be other variations, modifications, and alternatives.

Benefits are achieved over pre-existing techniques using the present invention. In particular, the present invention enables a cost-effective high pressure apparatus for growth of crystals such as GaN, AlN, InN, InGaN, and AlInGaN and others. In a specific embodiment, the present method and apparatus can operate with components that are relatively simple and cost effective to manufacture, such as ceramic and steel tubes. A specific embodiment also takes advantage of the one or more cracks provided in the ceramic member, which insulates the heater. Depending upon the embodiment, the present apparatus and method can be manufactured using conventional materials and/or methods according to one of ordinary skill in the art. The present apparatus and method enable cost-effective crystal growth and materials processing under extreme pressure and temperature conditions in batch volumes larger than 0.3 liters, larger than 1 liter, larger than 3 liters, larger than 10 liters, larger than 30 liters, larger than 100 liters, and larger than 300 liters according to a specific embodiment. In a preferred embodiment, the apparatus includes a release sleeve (or member or material0 that facilitates removal of the capsule without damaging the heater, capsule, or other elements in the apparatus after high temperature processing. Depending upon the embodiment, one or more of these benefits may be achieved. These and other benefits may be described throughout the present specification and more particularly below.

The present invention achieves these benefits and others in the context of known process technology. However, a further understanding of the nature and advantages of the present invention may be realized by reference to the latter portions of the specification and attached drawings.

### BRIEF DESCRIPTION OF THE DRAWINGS

FIG. 1 is a simplified diagram of a conventional apparatus.

FIG. 2 is a simplified diagram of a high pressure apparatus according to an embodiment of the present invention.

FIG. 3 is a simplified diagram of a cross-sectional view diagram of a high pressure apparatus according to an embodiment of the present invention.

FIG. 4 is a simplified diagram of a cross-sectional view diagram of a high pressure apparatus according to an embodiment of the present invention.

FIG. 5 is a simplified diagram of a cross-sectional view diagram of a high pressure apparatus according to an embodiment of the present invention.

FIG. 6 is a simplified diagram of a cross-sectional view diagram of a high pressure apparatus according to an embodiment of the present invention.

FIG. 7 is a simplified diagram of a close-up view of a cross-sectional view diagram of a high pressure apparatus according to an embodiment of the present invention.

FIG. 8 is a simplified flow diagram of a method of processing a material within a supercritical fluid according to an embodiment of the present invention.

### DETAILED DESCRIPTION OF THE INVENTION

According to the present invention, techniques for processing materials in supercritical fluids are included. More specifically, embodiments of the invention include techniques for material processing in a capsule disposed within a high-pressure apparatus/enclosure. Merely by way of example, the invention can be applied to growing crystals of GaN, AlN, InN, InGaN, AlGaN, and AlInGaN for manufacture of bulk or patterned substrates. Such bulk or patterned substrates can be used for a variety of applications including optoelectronic devices, lasers, light emitting diodes, solar cells, photo electrochemical water splitting and hydrogen generation, photodetectors, integrated circuits, and transistors.

In a specific embodiment, the present invention provides a high pressure apparatus for processing materials. Depending upon the embodiment, the apparatus has been described with reference to a specific orientation relative to the direction of gravity. As an example, the apparatus is described as being vertically oriented. In another embodiment, the apparatus is instead horizontally oriented or oriented at an oblique angle intermediate between vertical and horizontal, and may be rocked so as to facilitate convection of the supercritical fluid within the capsule. Of course, there can be other variations, modifications, and alternatives.

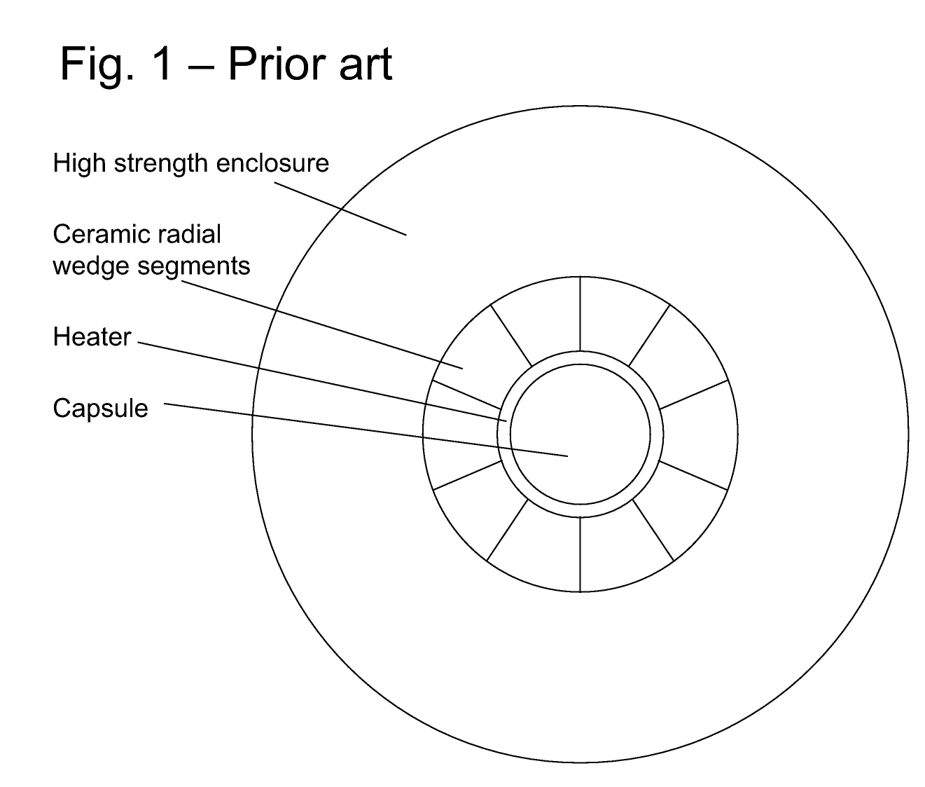

To provide a point of reference, the force-wedge apparatus described by D'Evelyn et al. in U.S. Patent Application No. 2006/0177362A1, which is incorporated by reference in its entirety herein, is shown in FIG. 1. A capsule, such as described in U.S. Pat. No. 7,125,453 or in U.S. patent application Ser. No. 12/133,365, entitled “Improved capsule for high pressure processing and method of use for supercritical fluids,” is placed within a re-usable heater, such as that described in U.S. Patent Application No. 2008/0083741A1 or in U.S. Patent Application No. 61/075,723, entitled “Heater device and method for high pressure processing of crystalline materials,” each of which is incorporated by reference herein. Both are contained within a high-strength enclosure, which may be fabricated from SA 723 pressure vessel steel. It is seen that the capsule is in direct contact with the heater, which may make removal difficult.

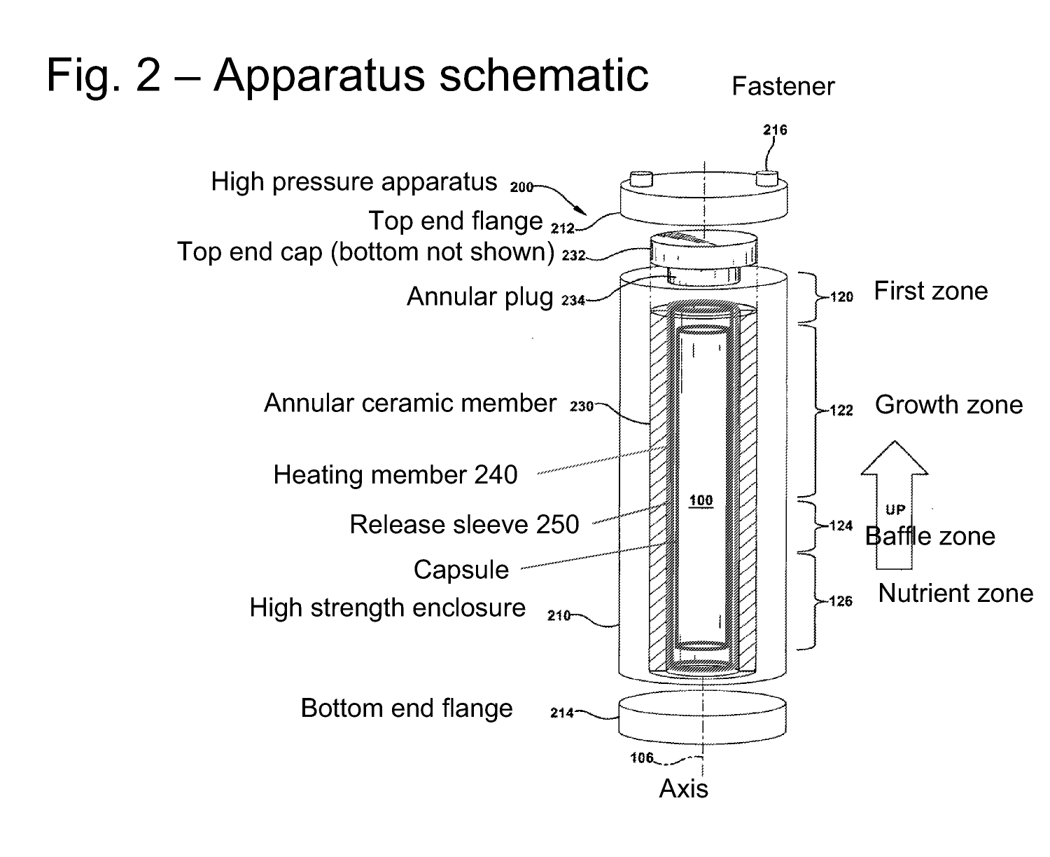

FIG. 2 is a simplified diagram of a high pressure apparatus according to an embodiment of the present invention. This diagram is merely an example, which should not unduly limit the scope of the claims herein. One of ordinary skill in the art would recognize other variations, modifications, and alternatives. As shown, the present invention provides an apparatus for high pressure crystal or material processing, e.g., GaN, AlN, InN, InGaN, AlGaN, and AlInGaN. Other processing methods include hydrothermal crystal growth of oxides and other crystalline materials, hydrothermal or ammonothermal syntheses, and hydrothermal decomposition, and others. Of course, there can be other variations, modifications, and alternatives.

Referring to FIG. 2, high pressure apparatus 200 and related methods for processing supercritical fluids are disclosed. In a specific embodiment, the present apparatus 200 includes a capsule 100, a release sleeve 250, a re-usable heating member or heater 240, at least one annular ceramic member 230 but can be wedges, multiple rings, optionally, with one or more scribe marks and/or cracks present. In a specific embodiment, the apparatus optionally has one or more metal containment sleeves (not shown) containing each ceramic ring or assembly of wedges. The apparatus also has a high-strength enclosure 210, end flanges 212, 214 with associated insulation, and a power control system. The apparatus is scalable up to very large volumes and is cost effective. In a specific embodiment, the apparatus is capable of accessing pressures and temperatures of 0.2-2 GPa and 400-1200° C., respectively. In a specific embodiment, the apparatus also includes a temperature controller. Of course, there can be other variations, modifications, and alternatives.

In a specific embodiment, apparatus 200 comprises at least one heat zone and optionally more, such as multiple, including two or more. The heat zones include an uppermost first zone 120, a growth zone 122, a baffle zone 124, and a charge or nutrient zone 126 according to a specific embodiment. When a capsule is inserted into the volume defined by a release sleeve inner surface, an internal baffle (not shown) aligns with the baffle gap zone according to a specific embodiment. The baffle defines two chambers inside the capsule, one for nutrient and one for growth according to a specific embodiment. The two chambers communicate through the perforated baffle, which can have various shapes and configurations. In the illustrated embodiment, appropriate for crystal growth when the solubility of the material to be recrystallized is an increasing function of temperature, the growth zone is located above the nutrient zone. In other embodiments, appropriate for crystal growth when the solubility of the material to be recrystallized is a decreasing function of temperature, i.e., retrograde solubility, the growth zone is located below the nutrient zone. In still other embodiments, apparatus 200 is approximately horizontal rather than vertical and may be fitted with a rocking mechanism (not shown).

In an embodiment, the capsule suitable for insertion inside the heater is formed from a precious metal. Examples of precious metals include platinum, palladium, rhodium, gold, or silver. Other metals can include titanium, rhenium, copper, stainless steel, zirconium, tantalum, alloys thereof, and the like. In an embodiment, the metal functions as an oxygen getter. Suitable capsule dimensions may be greater than 2 cm in diameter and 4 cm in length. In one embodiment, the dimension of the diameter is in a range selected from any of: 2-4 cm, 4-8 cm, 8-12 cm, 12-16 cm, 16-20 cm, 20-24 cm, and greater than 24 cm. In a second embodiment, the ratio of the length to diameter of the capsule is greater than 2. In yet another embodiment, the ratio of length to diameter is in a range of any of: 2 to 4, 4 to 6, 6 to 8, 8 to 9, 9 to 10, 10 to 11, 11 to 12, 12 to 14, 14 to 16, 16 to 18, 18 to 20, and greater than 20. Of course, there can be other variations, modifications, and alternatives.

In an embodiment, the growth zone 122 volume has twice the charge or nutrient zone 126 volume. The electrical circuits for each heating element segment are independently controlled. Independent control provides flexibility to achieve and maintain a heat deposition profile along the capsule height. A physical discontinuity between the second and third heater segments, from the top, produces a local dip in temperature near a baffle plate disposed in the capsule and separating the charge zone 126 from the growth zone 122. In an embodiment, the charge zone and the growth zone are isotherms at temperatures that differ from each other. The baffle zone has a temperature gradient over a relatively small distance between the charge zone and the growth zone isotherms. The power densities of the heating elements, and the resultant isotherms with minimal temperature gradient spacing therebetween minimize or eliminate wall nucleation inside the capsule and in or on the baffle. In an embodiment, the growth zone may be at the bottom and the charge zone at the top. Such configurations may be based on specific chemistries and growth parameters.

With particular reference to FIG. 2, the heater 240 is disposed in an apparatus 200 that includes a vessel or high strength enclosure 210. Attachable to the top end of the vessel is first end flange 212, and to the bottom end is a second end flange 214. A plurality of fasteners 216 (only one of which is indicated with a reference number) secure the end flanges to the vessel ends.

Within the vessel 200, annular ceramic member 230 lines the vessel inner surface and contacts the outer surface of the heater 240. Examples of annulus materials include but are not limited to zirconium oxide or zirconia. First and second end caps 232 (only one of which is shown) are located proximate to the ends of the heater 240 inside the vessel. An annular plug 234 is shown as stacked disks, but may be an annulus surrounding the cap 232. The plug 234 optionally can be disposed on at least one end and within a cavity between the capsule and the end flange to reduce axial heat loss and may comprise zirconium oxide or zirconia. Alternative plug materials may include magnesium oxide, salts, and phyllosilicate minerals such as aluminum silicate hydroxide or pyrophyllite according to a specific embodiment.

Apparatus 200 may include a pressure transmission medium between the axial ends of the capsule and the end caps and/or annular plugs according to a specific embodiment. The pressure transmission medium may comprise sodium chloride, other salts, or phyllosilicate minerals such as aluminum silicate hydroxide or pyrophyllite or other materials according to a specific embodiment. However, no significant quantity of pressure transmission medium is present between the heater and the annular ceramic member.

In a preferred embodiment, release sleeve 250 is positioned between the inner diameter of heater 240 and the outer diameter of capsule 100. Release sleeve 250 can be dissolved or etched or otherwise removed under conditions that do not produce significant dissolution or etching of heater 240 or capsule 100. In some embodiments, release sleeve 250 is soluble in cold or hot water. In some embodiments, release layer is soluble or etchable in base, such as at least one of NaOH, KOH, or NH₄OH, which will generally not attack heater 240 or capsule 100 if the latter are fabricated from metal. In some embodiments, release sleeve 250 is soluble or etchable in acid, such as at least one of HCl, HF, HNO₃, H₂SO₄, H₃PO₄, CH₃COOH, or HClO₄. A suitably chosen acid may not etch or dissolve heater 240 or capsule 100. In still other embodiments, release sleeve 250 is soluble or etchable by an oxidizing agent such as chromate, dichromate, permanganate, or hydrogen peroxide. In yet other embodiments, release sleeve 250 is soluble or etchable by an organic solvent such as alcohol, acetone, hexane, benzene, toluene, or trichloroethylene. Release sleeve 250 may comprise at least one of an alkali halide, such as NaCl, NaBr, NaF, KCl, or KBr, silver chloride, calcium fluoride, strontium fluoride, calcium carbonate, graphite, silicon dioxide, magnesium oxide, zirconium oxide, sodium silicate, iron, cobalt, nickel, copper, zinc, cadmium, indium, tin, antimony, tellurium, lead, and bismuth or combinations, and the like. Release sleeve 250 may be fabricated by methods that are known in the art, such as extrusion or dry-pressing of powder [P. W. Mirwald, et al., J. Geophys. Res. 80, 1519 (1975).] Release sleeve 250 may have a thickness between about 0.002″ and about 1″. In some embodiments, release layer 250 has a thickness between about 0.010″ and about 0.25″. Release sleeve 250 may have a length approximately equal to the length of the capsule, the length of the heater, or an intermediate value. In some embodiments release sleeve 250 additionally comprises an oxygen getter material, such as at least one of carbon, an alkali metal, an alkaline earth metal, Ti, V, Cr, Y, Zr, Nb, Hf, Ta, or a rare earth metal or combinations and the like. The getter material may comprise a powder and may be mixed with or embedded in the other material comprising the release sleeve.

The illustrated apparatus 200 can be used to grow crystals under pressure and temperature conditions desirable for crystal growth, e.g., gallium nitride crystals under related process conditions. The high-pressure apparatus 200 can include one or more structures operable to support the heater 240 radially, axially, or both radially and axially. The support structure in one embodiment thermally insulates the apparatus 200 from the ambient environment, and such insulation may enhance or improve process stability, maintain and control a desired temperature profile. Of course, there can be other variations, modifications, and alternatives.

In a specific embodiment, the apparatus includes a cylindrical capsule region comprising a first region and a second region, and a length defined between the first region and the second region. In a specific embodiment, a capsule is disposed within the cylindrical capsule region. As an example, the capsule is made of a suitable material that is chemically inert, can withstand pressure, and may also be easy to handle, among other features. Depending upon the embodiment, the capsule is made of a material selected from gold, platinum, silver, or palladium. Of course, there can also be other suitable materials, which can also include alloys, coatings, and/or multi-layered structures, depending upon the specific embodiment. Other metals can include titanium, rhenium, copper, stainless steel, zirconium, tantalum, alloys thereof, and the like. In a specific embodiment, the capsule is characterized by a deformable material and is substantially chemically inert relative to one or more reactants within the cylindrical capsule region. An example of a capsule is described in U.S. Pat. No. 7,125,453 or in U.S. patent application Ser. No. 12/133,365, entitled “Improved capsule for high pressure processing and method of use for supercritical fluids,” which are incorporated by reference herein for all purposes. Of course, there can be other variations modifications, and alternatives.

In a specific embodiment, the apparatus has an annular heating member enclosing the cylindrical capsule region. Another example of a heating member is described in U.S. Patent Application No. 2008/0083741A1 or in U.S. Patent Application No. 61/075,723, entitled “Heater device and method for high pressure processing of crystalline materials,” which are also incorporated by reference herein. The heating member may have at least two independently controllable hot zones and may be capable of generating heating power as large as 3 kilowatts, 10 kilowatts, 30 kilowatts, 100 kilowatts, 300 kilowatts, or 1000 kilowatts. Of course, there can be other variations, modifications, and alternatives.

In a specific embodiment, the apparatus has at least one annular ceramic or metal or cermet member having a predetermined thickness disposed around a perimeter of the annular heating member. The annular ceramic or metal or cermet member may be continuous or may comprise wedges arranged in a circle. In a specific embodiment, the annular member is made of a material having a compressive strength of about 0.5 GPa and greater and a thermal conductivity of about 4 watts per meter-Kelvin and less. As an example, the ceramic material can comprise rare earth metal oxide, zirconium oxide, hafnium oxide, magnesium oxide, calcium oxide, aluminum oxide, yttrium oxide, sialon (Si—Al—O—N), silicon nitride, silicon oxynitride, garnets, cristobalite, and mullite. The ceramic material may be a composite, comprising more than one phase. Alternatively, as an example, the metal can be a refractory metal such as tungsten, molybdenum, TZM alloy, and others. The cermet can be cobalt-cemented tungsten carbide, and others. In an alternative embodiment, which will be described further below, the annular ceramic, metal, or cermet member is configured to include a plurality of crack regions disposed in a non-symmetrical manner and disposed between an inner diameter of the continuous annular ceramic, metal, or cermet member and an outer diameter of the continuous annular ceramic, metal, or cermet member. In a specific embodiment, the annular member is one of a plurality of members, which are stacked on top of each other. Of course, there can be other variations, modifications, and alternatives.

In a specific embodiment, the apparatus also has a cylindrical sleeve member disposed overlying the at least annular ceramic, metal or cermet member. As an example, the cylindrical sleeve member is made of a material selected from stainless steel, iron, steel, iron alloy, nickel or nickel alloy, or any combinations thereof. In a specific embodiment, the cylindrical sleeve member comprises a first end and a second end. In a specific embodiment, the cylindrical sleeve has determined dimensions.

Depending upon the embodiment, the first end is characterized by a first outer diameter and the second end is characterized by a second outer diameter, which is less than the first outer diameter, to form a taper angle between an axis of the cylindrical sleeve member and an outer region of the cylindrical sleeve member, the taper angle ranging from about 0.1 to 5 Degrees. Of course, there can be other variations, modifications, and alternatives.

Additionally, the cylindrical sleeve member comprises a substantially constant inner diameter from the first end to the second end according to a specific embodiment, although the inner diameter can also vary depending upon the embodiment. In a preferred embodiment, the cylindrical sleeve member is configured to compress the continuous annular ceramic member in cooperation with the high pressure enclosure material. In a preferred embodiment, the cylindrical sleeve member is configured to provide mechanical support to maintain a determined shape of the continuous annular ceramic member. In a more preferred embodiment, the cylindrical sleeve is configured to compress the continuous annular ceramic member in cooperation with the high pressure enclosure material and is configured to provide mechanical support to maintain a determined shape of the annular ceramic member. Of course, there can be other variations, modifications, and alternatives.

In a specific embodiment, the apparatus has an high strength enclosure material disposed overlying the annular ceramic member. In a specific embodiment, the high strength enclosure is made of a suitable material to house internal contents including capsule, heater, sleeve, among other elements. In a specific embodiment, the high strength enclosure is made of a material selected from a group consisting of steel, low-carbon steel, SA723 steel, SA266 carbon steel, 4340 steel, A-286 steel, iron based superalloy, 304 stainless steel, 310 stainless steel, 316 stainless steel, 340 stainless steel, 410 stainless steel, 17-4 precipitation hardened stainless steel, zirconium and its alloys, titanium and its alloys, and other materials commonly known as Monel, Inconel, Hastelloy, Udimet 500, Stellite, Rene 41, and Rene 88. In a preferred embodiment, the high strength enclosure comprises a material with ultimate tensile strength, yield strength, and creep characteristics so as to be rated by the American Society of Mechanical Engineers for continuous operation as a pressure vessel at a pressure higher than 50,000 pounds per square inch. Of course, one of ordinary skill in the art would recognize other variations, modifications, and alternatives.

The high strength enclosure also has a desired length and width according to a specific embodiment. In a specific embodiment, the high strength enclosure has a length and an inner diameter to define an aspect ratio between about 2 to about 25. The high strength enclosure has a length and an inner diameter to define an aspect ratio of about ten to about twelve. In a specific embodiment, the inner diameter is between about two inches and about fifty inches. In a specific embodiment, the height of the high strength enclosure is between 6 inches and 500 inches. The ratio between the outer diameter and the inner diameter of the high strength enclosure may be between 1.2 and 5. In a specific embodiment, the diameter ratio may be between about 1.5 and about 3. Of course, there can be other variations, modifications, and alternatives. Further details of the present apparatus can be found throughout the present specification and more particularly below.

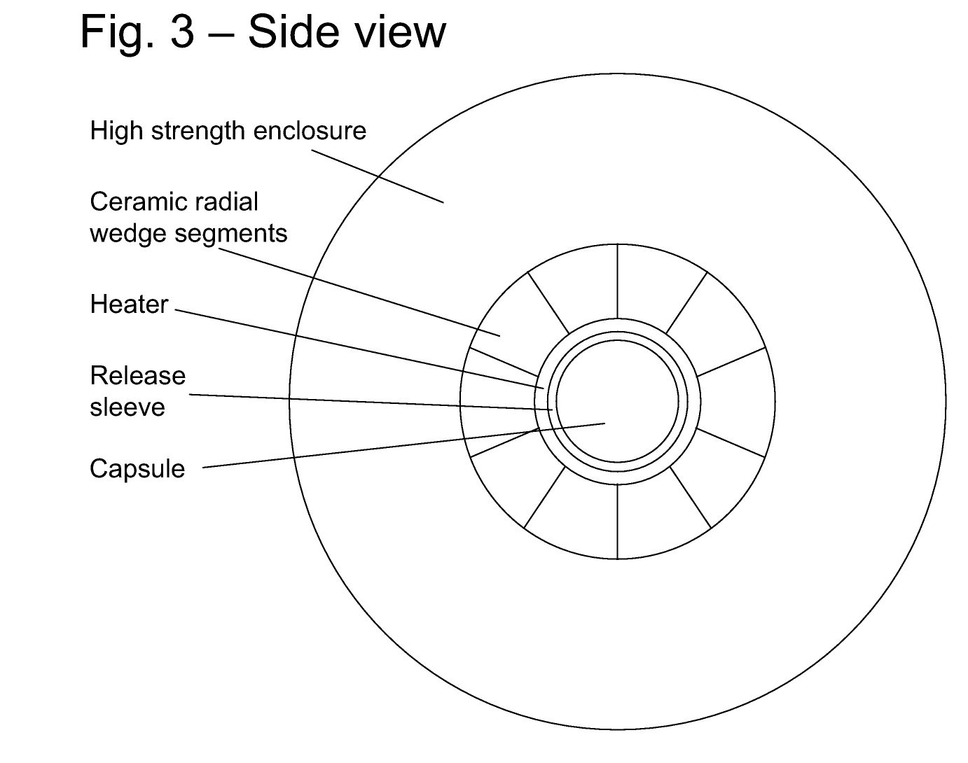

In a specific embodiment, the present apparatus 300 is illustrated by way of FIG. 3. This diagram is merely an example, which should not unduly limit the scope of the claims herein. One of ordinary skill in the art would recognize other variations, modifications, and alternatives. Annular ceramic member 307 comprises stacks of rings, each comprising wedge-shaped individual radial segments disposed one after another, within the apparatus. The ring may comprise a ceramic, such as alumina, silicon nitride, silicon carbide, zirconia, or the like, including other materials described herein as well as outside of the specification, which are known to one of ordinary skill in the art. The ring may alternatively comprise a refractory metal, such as tungsten, molybdenum, or TZM alloy, or a cermet, such as Co-cemented tungsten carbide. The ring may have an inner diameter between 0.5 inch and 24 inches, an outer diameter between 1 inch and 48 inches, and a height between 1 inch and 96 inches. In a specific embodiment, the inner diameter is between about 1.5 inches and about 8 inches and the height is between 1.5 inches and 8 inches. The ratio between the outer diameter and the inner diameter of the rings may be between 1.05 and 60. In a specific embodiment, the diameter ratio may be between about 1.5 and about 3. The ring may have a density greater than 95% of theoretical density. The modulus of rupture of the ring material may be greater than 200 or 450 MPa. The fracture toughness of the ring material may be greater than 9 MPa-m^{1/2}. Depending on the dimensions of the rings and of the high-strength enclosure, one to 200 rings may be stacked on top of one another inside the high-strength enclosure.

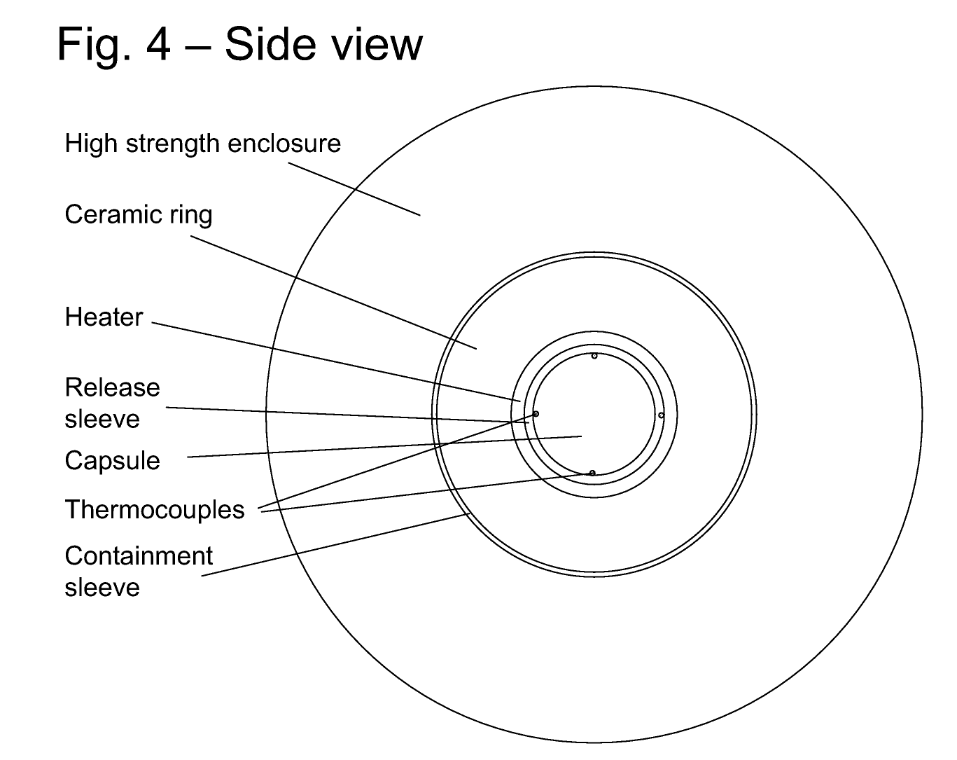

In another specific embodiment, the present apparatus 400 is illustrated by way of FIG. 4. This diagram is merely an example, which should not unduly limit the scope of the claims herein. One of ordinary skill in the art would recognize other variations, modifications, and alternatives. Instead of individual radial segments disposed one after another within the apparatus, one or more rings 407 may be stacked within the apparatus. The ring may comprise a ceramic, such as alumina, silicon nitride, silicon carbide, zirconia, or the like, including other materials described herein as well as outside of the specification, which are known to one of ordinary skill in the art. The ring may alternatively comprise a refractory metal, such as tungsten, molybdenum, or TZM alloy, or a cermet, such as Co-cemented tungsten carbide. The ring may have an inner diameter between 0.5 inch and 24 inches, an outer diameter between 1 inch and 48 inches, and a height between 1 inch and 96 inches. In a specific embodiment, the inner diameter is between about 1.5 inches and about 8 inches and the height is between 1.5 inches and 8 inches. The ratio between the outer diameter and the inner diameter of the rings may be between 1.05 and 60. In a specific embodiment, the diameter ratio may be between about 1.5 and about 3. The ring may have a density greater than 95% of theoretical density. The modulus of rupture of the ring material may be greater than 200 or 450 MPa. The fracture toughness of the ring material may be greater than 9 MPa-m^{1/2}. Depending on the dimensions of the rings and of the high-strength enclosure, one to 200 rings may be stacked on top of one another inside the high-strength enclosure.

In a specific embodiment, a spacer, with a thickness between 0.001 inch and 0.1 inch, may be placed between successive rings in the stack to allow for thermal expansion. A sleeve 409 may be placed around each ring. The sleeve may comprise steel or other suitable material according to a specific embodiment. The sleeve may be between 0.020 inch and 0.5 inch thick, and their height may be between 0.25 inch less than that of the ring and 0.1 inch greater than that of the ring depending upon the embodiment. The apparatus also includes a capsule 401, thermocouples 403, which are coupled electrically to temperature controller and/or power controller, a heater 405, a high strength enclosure 411, among other elements. Of course, there can be other variations, modifications, and alternatives.

In a specific embodiment the ceramic rings do not crack significantly under operating conditions, as represented in FIG. 4. The fracture strength of the rings may be higher than the operating pressure of the capsule, for example. In another embodiment, radial compressive loading of the rings is provided by an interference fit with the high strength enclosure. In an embodiment, an interference fit is achieved by at least one of heating of the high strength enclosure and cooling of the ring prior to assembly. In another embodiment, an interference fit is achieved by grinding a slight taper, for example, approximately one degree, on the inner diameter of the high strength enclosure and on the ring and/or the sleeve surrounding the ring, and then pressing the ring and sleeve into the high strength enclosure to achieve the interference fit.

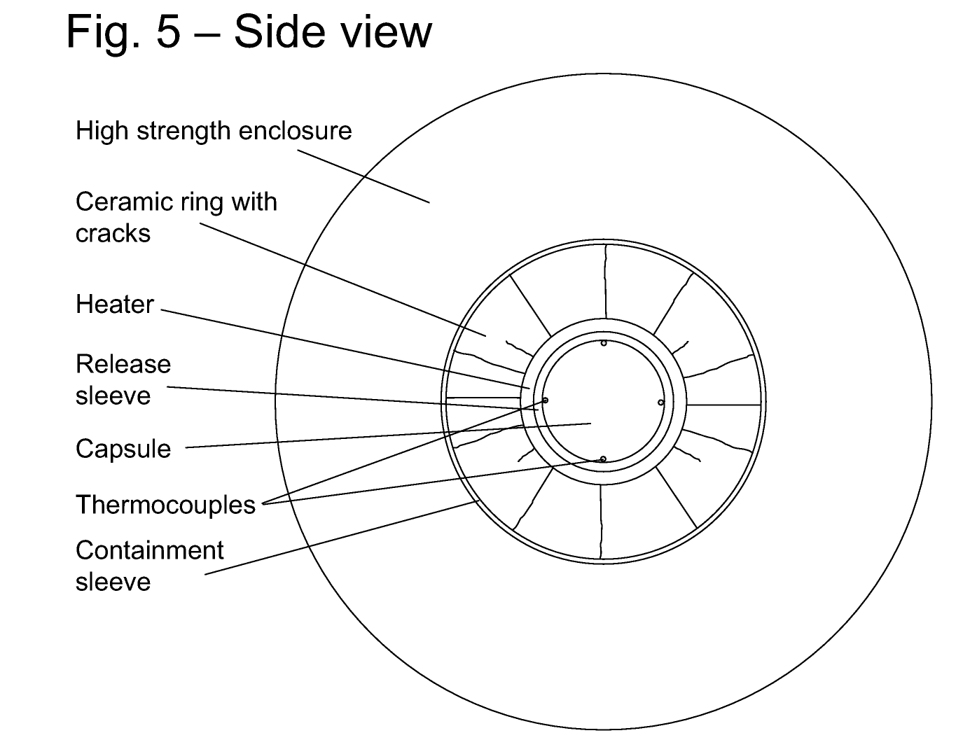

In another embodiment, the rings have at least one crack under operating conditions in the apparatus 500, as shown in FIG. 5. In a specific embodiment, the rings 507 are inserted into the high strength enclosure and allowed to crack during initial operation. Cracking in particular positions may be facilitated by scribing the inner diameter of the ring at the points of the desired crack initiation. The resulting cracks may run all the way from the inner diameter to the outer diameter, or they may terminate within the volume of the ring and/or have any combinations of these structures. In another embodiment, the rings are cracked prior to insertion into the high strength enclosure. Pre-cracking may be achieved by sliding a precision-turned rod having a larger coefficient of thermal expansion than the ring into the inner diameter of the ring and heating. The sleeve 509 surrounding the ring will keep and maintain all parts of the ring together and precisely oriented with respect to each other in the event that cracks run completely through the ring at various radial positions. In another embodiment, cracks are present within the volume of the ring and contact neither the inner diameter nor the outer diameter of the ring. The apparatus 500 also includes a capsule 501, thermocouples 503, which are coupled electrically to temperature controller and/or power controller, a heater 505, a high strength enclosure 511, among other elements. Of course, there can be other variations, modifications, and alternatives.

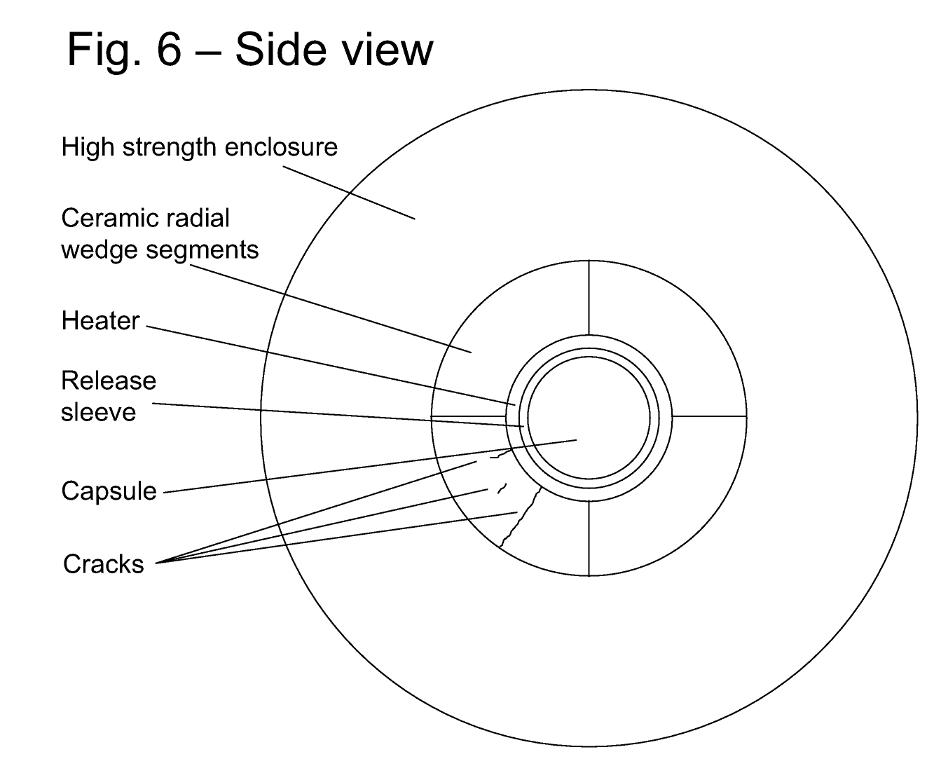

FIG. 6 is a simplified cross-sectional view diagram of an alternative high pressure apparatus according to an alternative embodiment of the present invention. In a specific embodiment, the two or more annular segments 657, which form a continuous ring structure, are inserted into the high strength enclosure and allowed to crack during initial operation. In a specific embodiment, there are two or more annular segments or three or more annular segments or four or more annular segments or other combinations, where each of the segments may have a similar length or different lengths. Cracking in particular positions may be facilitated by scribing the inner diameter of the two or more annular segments at the points of the desired crack initiation. The resulting cracks may run all the way from the inner diameter to the outer diameter, or they may terminate within the volume of the two or more annular segments and/or have any combinations of these structures.

In another embodiment, the two or more annular segments are cracked prior to insertion into the high strength enclosure. Pre-cracking may be achieved by sliding a precision-turned rod having a larger coefficient of thermal expansion than the two or more annular segments into the inner diameter of the segmented rings and heating them. The sleeve 409 surrounding the segments will keep and maintain all parts of the segments together and precisely oriented with respect to each other, including the case where cracks run completely through the ring segments at various radial positions. In another embodiment, cracks are present within the volume of the segments and contact neither the inner diameter nor the outer diameter of the segments. The apparatus 650 also includes a capsule 651, thermocouples 653, which are coupled electrically to temperature controller and/or power controller, a heater 655, a high strength enclosure 661, among other elements.

In a specific embodiment, the present method and related annular segments include slight irregularities and/or imperfections. In a specific embodiment, the segments are made of a suitable material that can accommodate itself by cracking. Additionally, slight changes in dimensions of each of the ceramic members are also accommodated by the cracks, which allows the assembly to be disposed around the heating member in a substantially continuous manner. In a specific embodiment, the present apparatus and related device prevents any rupture of a capsule and/or high strength enclosure by providing a buffer and/or insulating region between the capsule and high strength enclosure. Of course, there can be other variations, modifications, and alternatives.

The vertical dimension runs out of the page in FIGS. 3, 4, 5 and 6. The top and bottom of the cavity defined by the inner diameter of the rings or by the inner diameter of the release sleeve is terminated by insulating plugs positioned proximate to end flanges, as shown in FIG. 2. The end flanges may be attached to the high strength enclosure by means of bolts. The length-to-diameter ratio of the cavity should be at least 2:1 and more preferably lies in the range between 5:1 and 15:1.

In order to measure the temperature at various heights on the outer diameter of the capsule, prior to assembly at least one axial dent or groove is placed on the outer diameter of the capsule at specified radial positions. In the examples shown in FIGS. 4 and 5, four dents or grooves are placed 90 degrees apart along the outer diameter of the capsule. The groove or dent may extend the entire height of the capsule or may terminate at the height along the capsule where a temperature measurement is desired. The width and depth of the groove or dent may be between about 0.025 inch and 0.130 inch. Holes slightly larger in diameter than the thermocouple may be placed in one or both end flanges. Holes or grooves may also be placed in at least one insulating cylinder separating the end flange from the capsule. Thermocouples may be inserted into the grooves or dents after insertion of the capsule into the heater, followed by placement of the end flanges onto the high strength enclosure. Alternatively, one or more thermocouples may be inserted into the grooves or dents prior to placement of the end flanges, and the free ends strung through the end flanges prior to placement of the latter and attachment of the electrical connections to the free ends of the thermocouples. Further details of methods according to embodiments of the present invention are provided below.

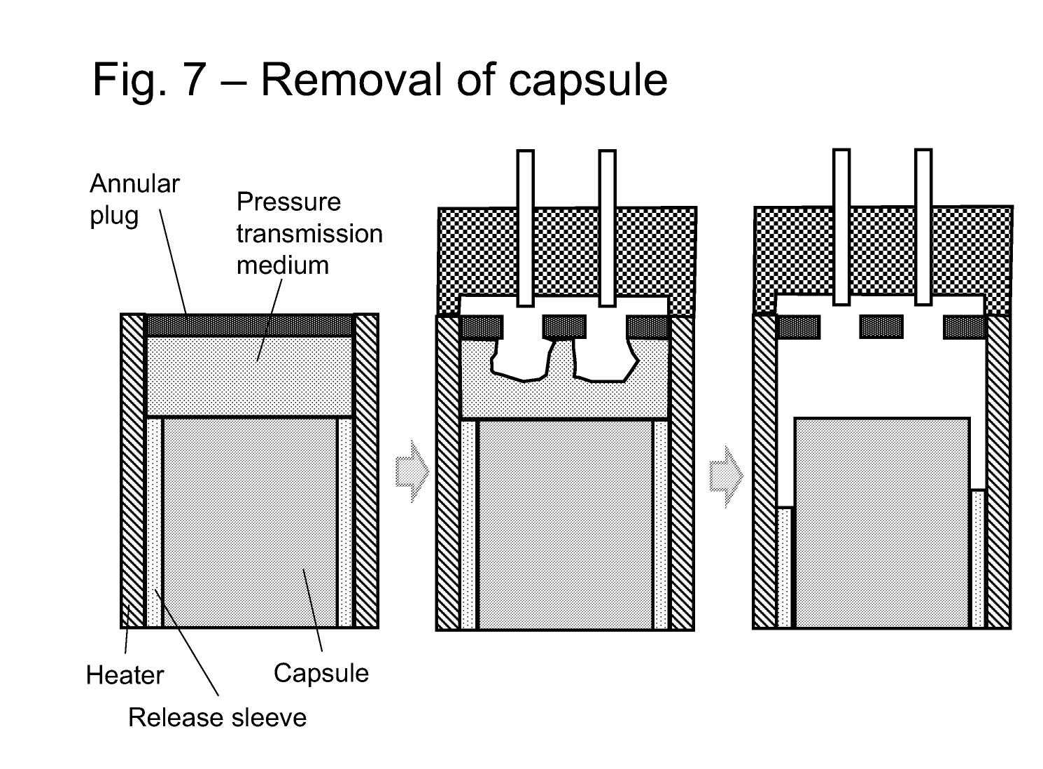

The release sleeve facilitates removal of the capsule from the apparatus at the conclusion of a run. After cooling the capsule and opening the ends of the high pressure apparatus, the end flanges and end caps are removed, exposing the ends of the heater. The upper portion of the exposed heater is shown schematically in FIG. 7, with an annular plug now being exposed and a pressure transmission medium material disposed between the plug and the capsule and the release sleeve separating the capsule and the heater. Optionally, the solvent may be removed from the capsule by perforating the annular plug, the pressure transmission medium, and the capsule end. In a preferred embodiment, the pressure transmission medium may be dissolved or etched by the same release sleeve solvent which can dissolve or etch the release sleeve without significant dissolution or etching of the heater or the capsule. However, the annular plug may not be readily dissolved or etched by the release sleeve solvent, and it may be perforated in one or more locations, for example, by drilling one or more holes. One or more solvent flanges, each with an inlet and an outlet for release sleeve solvent, may then be coupled to the end(s) of the heater. A seal may be provided between the solvent flange and the heater by means of a elastomer gasket, an o-ring, wax, or the like. The release sleeve solvent is then injected into the inlet to the solvent flange and allowed to exit though the outlet. The release sleeve solvent begins to dissolve or etch the pressure transmission medium, as shown in FIG. 7. As the process continues the release sleeve solvent begins to dissolve or etch the release sleeve. The dissolution or etching process may be carried out at room temperature or at elevated temperature. An elevated dissolution or etching temperature may be achieved by providing electrical power to the heater.

In one embodiment, at least partial removal of the release sleeve and pressure transmission medium is performed first on the bottom end of the heater, with the capsule being held in place by the pressure transmission medium and/or annular plug at the top end of the heater. Then, mechanical support is provided for the bottom end of the capsule while the release sleeve and pressure transmission medium is at least partially dissolved or etched at the top end of the heater so that it does not fall suddenly, possibly damaging the crystals inside the capsule.

After at least partial dissolution of the release sleeve, the annular plugs are removed, if present, and the capsule is removed from the heater. The capsule may then be opened to remove the crystals.

A method according to a specific embodiment is briefly outlined below.

1. Provide an apparatus for high pressure crystal growth or material processing, such as the one described above, but can be others, the apparatus comprising a cylindrical capsule region comprising a first region and a second region, and a length defined between the first region and the second region, an annular heating member enclosing a release sleeve and the release sleeve enclosing the cylindrical capsule region, at least one annular ceramic or metal or cermet member having a predetermined thickness disposed continuously around a perimeter of the annular heating member and an high strength enclosure material disposed overlying the annular ceramic member;

2. Provide a capsule containing a solvent;

3. Place the capsule within an interior region of the cylindrical capsule region;

4. Process the capsule with thermal energy to cause an increase in temperature within the capsule to greater than 200 Degrees Celsius to cause the solvent to be superheated;

5. Form a crystalline material from a process of the superheated solvent;

6. Remove thermal energy from the capsule to cause a temperature of the capsule to change from a first temperature to a second temperature, which is lower than the first temperature;

7. Remove a first flange and a second flange from the high pressure apparatus;

8. Dissolve or etch at least a portion of the release sleeve and remove the capsule from the cylindrical capsule region;

9. Open the capsule;

10. Remove the crystalline material; and

11. Perform other steps, as desired.

The above sequence of steps provides a method according to an embodiment of the present invention. In a specific embodiment, the present invention provides a method and resulting crystalline material provided by a high pressure apparatus having structured support members. Other alternatives can also be provided where steps are added, one or more steps are removed, or one or more steps are provided in a different sequence without departing from the scope of the claims herein. Details of the present method and structure can be found throughout the present specification and more particularly below.

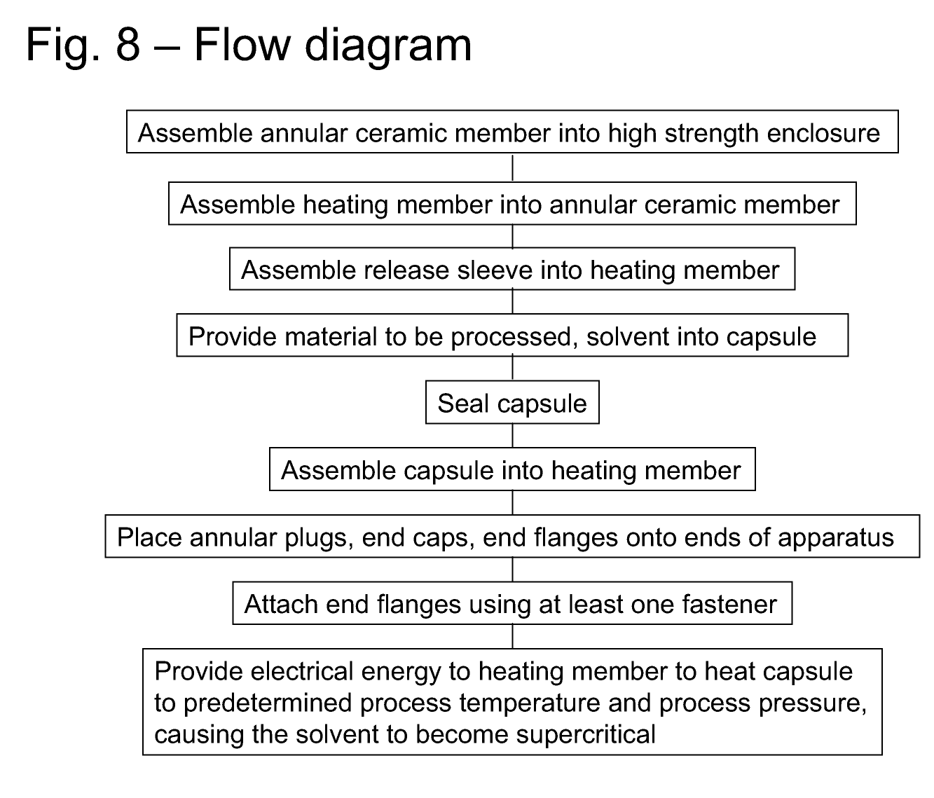

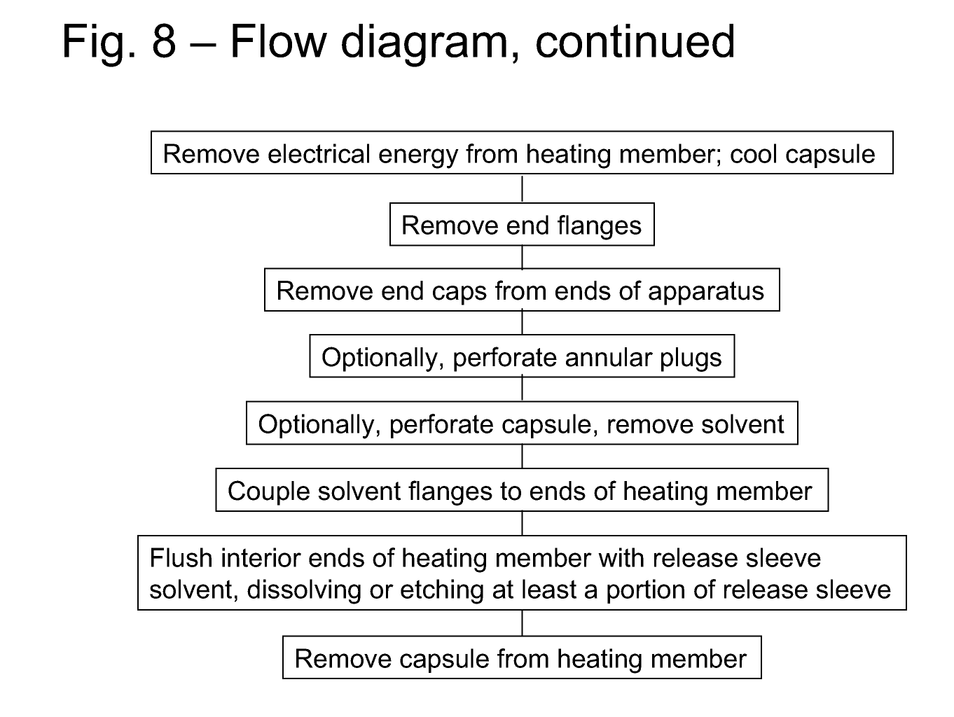

FIG. 8 is a simplified diagram 800 of a method of processing a supercritical fluid according to an embodiment of the present invention. This diagram is merely an example, which should not unduly limit the scope of the claims herein. One of ordinary skill in the art would recognize other variations, modifications, and alternatives. In a specific embodiment, the method beings with start, step 801. The method begins by providing an apparatus for high pressure crystal or material processing, such as the one described above, but can be others. In a specific embodiment, the apparatus has a cylindrical capsule region comprising a first region and a second region, and a length defined between the first region and the second region. The apparatus also has an annular heating member enclosing a release sleeve, the release sleeve enclosing the cylindrical capsule region, at least one ceramic or annular metal or cermet member having a predetermined thickness disposed continuously around a perimeter of the annular heating member and a high strength enclosure material disposed overlying the annular ceramic member. Of course, there can be other variations, modifications, and alternatives.

In a specific embodiment, the method provides a capsule containing a solvent, such as ammonia, for example. In a specific embodiment, the method places the capsule containing the solvent and starting crystal within an interior region of the cylindrical capsule region. The method processes the capsule with thermal energy to cause an increase in temperature within the capsule to greater than 200 Degrees Celsius to cause the solvent to be superheated. Of course, there can be other variations, modifications, and alternatives.

Referring again to FIG. 8, the method forms a crystalline material from a process of the superheated solvent. In a preferred embodiment, the crystalline material is gallium containing crystal such as GaN, AlGaN, InGaN, and others. In a specific embodiment, the method removes thermal energy from the capsule to cause a temperature of the capsule to change from a first temperature to a second temperature, which is lower than the first temperature. Once the energy has been removed and temperature reduced to a suitable level, the method removes one or more flanges, which mechanically held at least the capsule in place. In a preferred embodiment, the method perform at least partial dissolution or etching of the release sleeve to enable transfer of the capsule out of the cylindrical capsule region free from the apparatus without excessive force, which might otherwise deform the capsule and/or damage the crystals.

In a specific embodiment, the capsule is now free from the apparatus. In a specific embodiment, the capsule is opened. In a preferred embodiment, the crystalline material is removed from an interior region of the capsule. Depending upon the embodiment, there can also be other steps, which can be inserted or added or certain steps can also be removed. In a specific embodiment, the method ends at stop. Of course, there can be other variations, modifications, and alternatives.

The above sequence of steps provides a method according to an embodiment of the present invention. In a specific embodiment, the present invention provides a method and resulting crystalline material provided by a high pressure apparatus having structured support members. Other alternatives can also be provided where steps are added, one or more steps are removed, or one or more steps are provided in a different sequence without departing from the scope of the claims herein.

A method according to an alternative specific embodiment is briefly outlined below.

1. Assemble an apparatus for high pressure crystal or material processing, such as the one described above, but can be others, the apparatus comprising a cylindrical capsule region comprising a first region and a second region, and a length defined between the first region and the second region, an annular heating member enclosing a release sleeve, the release sleeve enclosing the cylindrical capsule region, at least one annular ceramic or metal or cermet member having a predetermined thickness disposed continuously around a perimeter of the annular heating member and an high strength enclosure material disposed overlying the annular ceramic member;

2. Provide material to be processed and solvent in a capsule;

3. Place the capsule within an interior region of the cylindrical capsule region;

4. Place annular plugs, end caps, end flanges onto ends of the apparatus;

5. Attach end flanges using at least one fastener;

6. Provide electrical energy to heating member to cause an increase in temperature within the capsule to greater than 200 Degrees Celsius to cause the solvent to be superheated;

7. Form a crystalline material from a process of the superheated solvent;

8. Remove thermal energy from the capsule to cause a temperature of the capsule to change from a first temperature to a second temperature, which is lower than the first temperature;

9. Remove a first flange and a second flange from the high pressure apparatus;

10. Dissolve or etch at least a portion of the release sleeve and remove the capsule from the cylindrical capsule region;

11. Open the capsule;

12. Remove the crystalline material; and

13. Perform other steps, as desired.

The above sequence of steps provides a method according to an embodiment of the present invention. In a specific embodiment, the present invention provides a method and resulting crystalline material provided by a high pressure apparatus having structured support members. Other alternatives can also be provided where steps are added, one or more steps are removed, or one or more steps are provided in a different sequence without departing from the scope of the claims herein. Details of the present method and structure can be found throughout the present specification and more particularly below.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. Apparatus for high pressure crystal or material processing, the apparatus comprising:
a cylindrical capsule region comprising a first region and a second region, and a length defined between the first region and the second region;
an annular heating member overlying a portion of the length between the first region and the second region;
a release sleeve disposed between the cylindrical capsule region and the annular heating member, the release sleeve being configured to be dissolved and/or etched under one or more process conditions without producing substantial dissolution and/or etching of the annular heating member;
at least one annular ceramic member having a predetermined thickness disposed continuously around a perimeter of the annular heating member, the annular member being made of a material having a compressive strength of about 0.5 GPa and greater and a thermal conductivity of about 4 watts per meter-Kelvin and less; and
a high strength enclosure material disposed overlying the annular ceramic member to form a high strength enclosure.

2. Apparatus of claim 1 wherein the release sleeve fully or partially enclosing the length of the cylindrical capsule region.

3. Apparatus of claim 1 wherein the high strength enclosure is configured to withstand a load of greater than about 0.1 GPa for a predetermined time period and a temperature of 200 Degrees Celsius and below.

4. Apparatus of claim 1 wherein further comprising a capsule disposed within the cylindrical capsule region.

5. Apparatus of claim 4 wherein the release sleeve is dissolvable or etchable in at least one of water, a base, an acid, or an organic solvent.

6. Apparatus of claim 4 wherein the release sleeve comprises at least one of an alkali halide, silver chloride, calcium fluoride, strontium fluoride, calcium carbonate, graphite, silicon dioxide, magnesium oxide, zirconium oxide, sodium silicate, iron, cobalt, nickel, copper, zinc, cadmium, indium, tin, antimony, tellurium, lead, and bismuth.

7. Apparatus of claim 6 wherein the release sleeve comprises at least one of NaCl, NaBr, NaF, KCl, or KBr.

8. Apparatus of claim 4 wherein the release sleeve has a thickness between about 0.002″ and about 1″.

9. Apparatus of claim 8 wherein the release sleeve has a thickness between about 0.010″ and about 0.25″.

10. Apparatus of claim 4 wherein the cylindrical sleeve member further comprises an oxygen getter material.

11. Apparatus of claim 10 wherein the oxygen getter material comprises at least one of carbon, an alkali metal, an alkaline earth metal, Ti, V, Cr, Y, Zr, Nb, Hf, Ta, or a rare earth metal.

12. Apparatus for high pressure crystal or material processing, the apparatus comprising:
a cylindrical capsule region comprising a first region and a second region, and a length defined between the first region and the second region;
an annular heating member overlying a release sleeve, the release sleeve enclosing the length of the cylindrical capsule region, the release sleeve configured to be dissolved and/or etched under one or more process conditions without producing substantial dissolution and/or etching of the annular heating member;
at least one annular metal or cermet member having a predetermined thickness disposed continuously around a perimeter of the annular heating member, the continuous annular member being made of a material having a compressive strength of about 0.5 GPa and greater and a thermal conductivity of about 100 watts per meter-Kelvin and less; and
a high strength enclosure material disposed overlying the annular metal or cermet member to form a high strength enclosure.

13. Apparatus of claim 12 wherein the high strength enclosure is configured to withstand a load of greater than about 0.1 GPa for a predetermined time period.

14. Apparatus of claim 12 wherein further comprising a capsule disposed within the cylindrical capsule region.

15. Apparatus of claim 14 wherein the release sleeve is dissolvable or etchable in at least one of water, a base, an acid, or an organic solvent.

16. Apparatus of claim 14 wherein the release sleeve comprises at least one of an alkali halide, silver chloride, calcium fluoride, strontium fluoride, calcium carbonate, graphite, silicon dioxide, magnesium oxide, zirconium oxide, sodium silicate, iron, cobalt, nickel, copper, zinc, cadmium, indium, tin, antimony, tellurium, lead, and bismuth.

17. Apparatus of claim 14 wherein the release sleeve comprises at least one of NaCl, NaBr, NaF, KCl, or KBr.

18. Apparatus of claim 14 wherein the release sleeve has a thickness between about 0.005″ and about 1″.

19. Apparatus of claim 18 wherein the release sleeve has a thickness between about 0.020″ and about 0.25″.

20. Apparatus of claim 14 wherein the cylindrical sleeve member further comprises an oxygen getter material.

21. Apparatus of claim 19 wherein the oxygen getter material comprises at least one of carbon, an alkali metal, an alkaline earth metal, Ti, V, Cr, Y, Zr, Nb, Hf, Ta, or a rare earth metal.

22. A method of crystal growth, the method comprising:
providing an apparatus for high pressure crystal or material processing, the apparatus comprising:
a cylindrical capsule region comprising a first region and a second region, and a length defined between the first region and the second region;
an annular heating member overlying a release sleeve, the release sleeve enclosing the length of the cylindrical capsule region, the release sleeve configured to be dissolved and/or etched under one or more process conditions without producing substantial dissolution and/or etching of the annular heating member;
at least one annular ceramic or metal or cermet member having a predetermined thickness disposed continuously around a perimeter of the annular heating member, the continuous annular member being made of a material having a compressive strength of about 0.5 GPa and greater and a thermal conductivity of about 100 watts per meter-Kelvin and less;
a high strength enclosure material disposed overlying the annular ceramic member;
providing a capsule containing a solvent;
placing the capsule within an interior region of the cylindrical capsule region; and
processing the capsule with thermal energy to cause an increase in temperature within the capsule to greater than 200 Degrees Celsius to cause the solvent to be superheated.

23. The method of claim 22 further comprising forming or recrystallizing a crystalline material from a process of the superheated solvent.

24. The method of claim 23 further comprising removing thermal energy from the capsule to cause a temperature of the capsule to change from a first temperature to a second temperature, the second temperature being lower than the first temperature.

25. The method of claim 23 further comprising removing a first flange and a second flange from the high pressure apparatus; dissolving or etching at least a portion of the release sleeve; and removing the capsule from the cylindrical capsule region.
